(19) United States
(12) Patent Application Publication
(10) Pub. No.: US 2026/0267321 A1
(43) Pub. Date: Sep. 10, 2026

(54) OPTIMIZED SYSTEM AND METHOD FOR SOLDER BALL FLATTENING IN PRINTED CIRCUIT BOARD MANUFACTURING PROCESS

(71) Applicant: NAN YA PLASTICS CORPORATION, Taipei City (TW)

(72) Inventors: Ching-Yao Yuan, Taipei City (TW); Cheng-Li Chao, Taipei City (TW); Yu Ti Tseng, Taipei City (TW); Meng-Huai Han, Taipei City (TW)

(73) Assignee: NAN YA PLASTICS CORPORATION, Taipei City (TW)

(21) Appl. No.: 19/093,194

(22) Filed: Mar. 27, 2025

(30) Foreign Application Priority Data
Mar. 4, 2025 (TW) 114107988

(51) Int. Cl. G05B 19/418; H05K 3/34

(52) U.S. Cl. CPC G05B 19/41885; H05K 3/3465; G05B 2219/33002; G05B 2219/45026; G05B 2219/45029; H05K 2203/0465

(57) ABSTRACT

Disclosed are an optimized system and method for solder ball flattening in a printed circuit board manufacturing process, which may generate corresponding flattening condition parameters based on machine characteristics and material characteristics. In subsequent processes, the flattening condition parameters recommended by an optimization model may be used to reduce a problem of poor flattening yield. Through the content of the disclosure, not only can a process of performing trial pressing with a small quantity of sample during trial mass production be decreased, but the flattening yield can also be enhanced to reduce rework.

### CROSS-REFERENCE TO RELATED APPLICATION

This application claims the priority benefit of Taiwan application serial no. 114107988, filed on Mar. 4, 2025. The entirety of the above-mentioned patent application is hereby incorporated by reference herein and made a part of this specification.

### BACKGROUND

### Technical Field

The disclosure relates to an optimized system and method for a manufacturing process, and in particular relates to an optimized system and method for solder ball flattening in a printed circuit board manufacturing process.

### Related Art

The back end of line of a printed circuit board manufacturing process mainly includes a solder resist station and solder ball or solder paste mounting (bumping), followed by flattening of the solder ball or solder paste. Before shipping, the finished product needs to be inspected to confirm the yield. The foregoing yield may be affected by differences in the solder resist opening size and thickness of each production batch. Therefore, before the solder ball (or solder paste) flattening production, a small quantity of sample needs to be taken for trial pressing and measurement, and then the flattening condition is determined by experience, which occasionally results in a poor flattening yield or even a rework phenomenon where a second flattening needs to be arranged. Therefore, how to propose a system to select key parameters before performing the manufacturing process of solder ball flattening to find an optimized flattening production condition is an important topic.

### SUMMARY

In view of this, the disclosure provides an optimized system and method for solder ball flattening in a printed circuit board manufacturing process, which performs modeling through using data of a past manufacturing process to provide a flattening production condition for solder ball flattening in the manufacturing process.

The disclosure provides an optimized system for solder ball flattening in a printed circuit board manufacturing process, which includes a storage and a processor. The storage stores multiple modules. The processor is coupled to the storage and configured to: obtain multiple data; perform a preprocessing on the data; the preprocessing includes performing a classification on the data based on processing machine characteristics and processing material characteristics; execute a parameter selection module among the modules to obtain multiple parameters based on the data; execute a machine learning module among the modules to establish an optimization model based on the data that have been preprocessed and the parameters; and execute a prediction module among the modules to perform a reverse prediction testing on the optimization model.

The disclosure further provides an optimized method for solder ball flattening in a printed circuit board manufacturing process, which includes: multiple data are obtained; a preprocessing is performed on the multiple data; the preprocessing includes performing a classification on the data based on processing machine characteristics and processing material characteristics; multiple parameters are obtained based on the data; an optimization model is established based on the data that have been preprocessed and the parameters; and a reverse prediction testing is performed on the optimization model.

Based on the above, the optimized system and method for solder ball flattening in the printed circuit board manufacturing process provided by the disclosure may generate corresponding flattening condition parameters based on machine characteristics and material characteristics. In subsequent manufacturing processes, the flattening condition parameters recommended by the optimization model may be used to reduce a problem of poor flattening yield. Through the content of the disclosure, not only can a process of performing trial pressing with a small quantity of sample during trial mass production be decreased, but the flattening yield can also be enhanced to reduce rework.

### BRIEF DESCRIPTION OF THE DRAWINGS

FIG. 1 is a schematic diagram of an optimized system for solder ball flattening in a printed circuit board manufacturing process according to the disclosure.

FIG. 2 is a schematic flow chart for executing an optimized system for solder ball flattening in a printed circuit board manufacturing process according to the disclosure.

FIG. 3 is a schematic flow chart for producing a printed circuit board.

FIG. 4 is a detailed schematic flow chart for executing an optimized system for solder ball flattening in a printed circuit board manufacturing process according to the disclosure.

### DESCRIPTION OF THE EMBODIMENTS

Reference will now be made in detail to exemplary embodiments of the disclosure, examples of which are illustrated in the accompanying drawings. Throughout the specification (including the claims), the terms “first,” “second,” etc. are used to name elements or to distinguish different embodiments or scopes, and are not intended to limit the maximum or minimum number of elements, nor to limit the order of the elements. In addition, wherever possible, elements/components/steps with the same reference numerals in the drawings and embodiments represent the same or similar components.

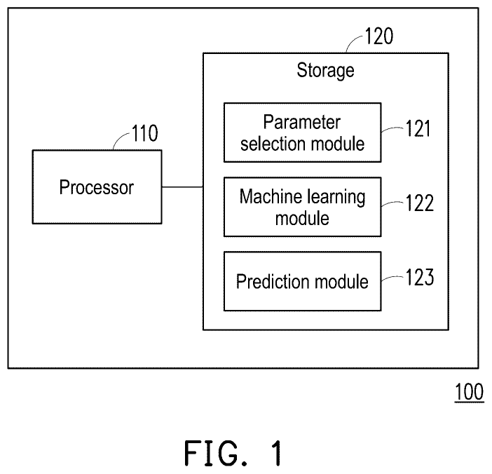

FIG. 1 is a schematic diagram of an optimized system for solder ball flattening in a printed circuit board manufacturing process according to the disclosure. An optimized system 100 for solder ball flattening in the printed circuit board manufacturing process may include a processor 110 and a storage 120.

In the embodiment of the disclosure, the processor 110 is, for example, a central processing unit (CPU), or other programmable general-purpose or special-purpose micro control unit (MCU), microprocessor, digital signal processor (DSP), programmable controller, application specific integrated circuit (ASIC), graphics processing unit (GPU), image signal processor (ISP), image processing unit (IPU), arithmetic logic unit (ALU), complex programmable logic device (CPLD), field programmable gate array (FPGA), or other similar elements or a combination of the foregoing elements. In the process parameter optimized system 100, the processor 110 may be coupled to the storage 120. The processor 110 may execute each module stored in the storage 120.

The storage 120 is, for example, any type of fixed or movable random access memory (RAM), read-only memory (ROM), flash memory, hard disk drive (HDD), solid state drive (SSD), or similar elements or a combination of the foregoing elements, and configured to store multiple models or various applications that may be executed by the processor 110. In the embodiment, the storage 120 may at least store a parameter selection module 121, a machine learning module 122, and a prediction module 123.

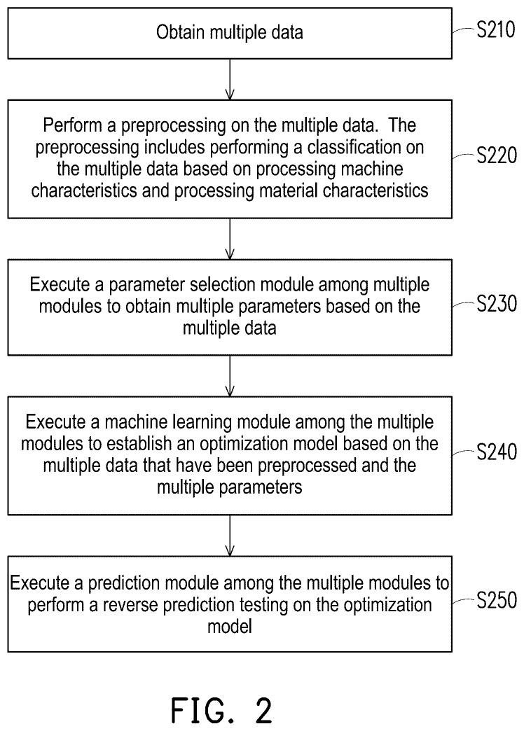

Please refer to FIG. 2. FIG. 2 is a schematic flow chart for executing an optimized system for solder ball flattening in a printed circuit board manufacturing process according to the disclosure. In procedure S210, the processor 110 may obtain multiple data. In procedure S220, the processor 110 may perform a preprocessing on the multiple data. The preprocessing includes performing a classification on the multiple data based on processing machine characteristics and processing material characteristics. In procedure S230, the processor 110 may execute the parameter selection module among multiple modules to obtain multiple parameters based on the multiple data. In procedure S240, the processor 110 may execute the machine learning module among the multiple modules to establish an optimization model based on the multiple data that have been preprocessed and the multiple parameters. In procedure S250, the processor 110 may execute the prediction module among the multiple modules to perform a reverse prediction testing on the optimization model.

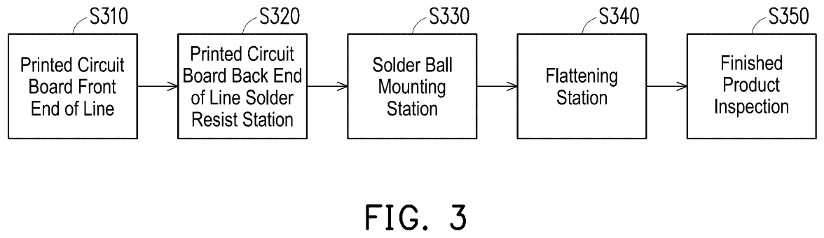

FIG. 3 is a schematic flow chart for producing a printed circuit board, which is a known manufacturing process of the printed circuit board, including procedure S310 of a printed circuit board front end of line, procedure S320 of a solder resist station in a printed circuit board back end of line, procedure S330 of a solder ball mounting station, procedure S340 of a flattening station, and procedure S350 of finished product inspection. In the embodiment of the disclosure, an optimization of the manufacturing process is mainly focused on procedure S320 and procedure S330. In the embodiment of the disclosure, the processor 110 may first obtain multiple past process data of the foregoing procedure S320 and procedure S330 to be used for subsequent establishment of the optimization model.

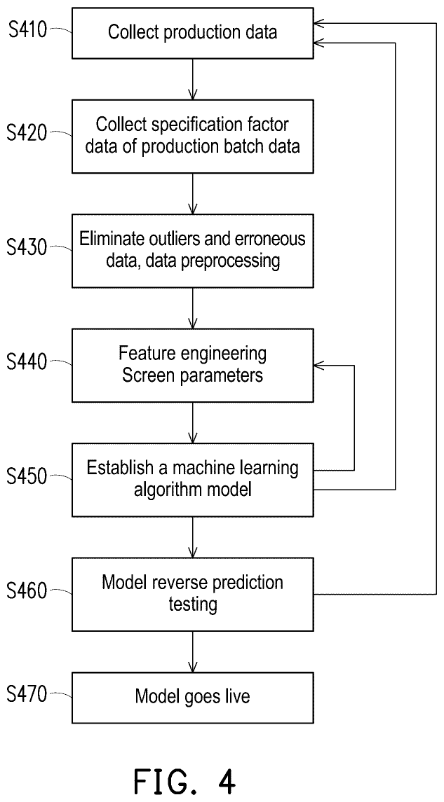

Please refer to FIG. 4. FIG. 4 is a detailed schematic flow chart for executing an optimized system for solder ball flattening in a printed circuit board manufacturing process according to the disclosure. In procedure S410, the processor 110 may collect production data, such as obtaining multiple past process data of the foregoing procedure S320 and procedure S330. In procedure S420, the processor 110 may collect specification factor data of production batch data. Specifically, the specification factor data, that is, parameters, may include production parameters and measurement parameters of the solder resist process, production parameters and measurement parameters of the solder ball (solder paste) mounting process station, and specification parameters of different types of film material used in the production batch.

Please continue to refer to FIG. 4. In procedure S430, the processor 110 may eliminate outliers and erroneous data, and data preprocessing. The preprocessing may at least include performing a classification on the process data based on processing machine characteristics and processing material characteristics in the data. For example, during the process of producing a printed circuit board, different processing machines may have different characteristics. Using processing machines with different characteristics might result in different parameters that need to be emphasized during the manufacturing process. Furthermore, processing machines with different parts or different years of usage might result in different parameters that need to be emphasized during the manufacturing process. Alternatively, using different proportions of multiple materials or different material styles might also result in different parameters that need to be emphasized during the manufacturing process. Therefore, the processor 110 may perform the classification on the data based on the different processing machine characteristics and processing material characteristics, so that when similar processing machines and similar processing materials are used, a model established with corresponding data may be taken to select the parameters that need to be emphasized.

In the embodiment of the disclosure, key parameters affecting the manufacturing process may include solder resist open annulus size, flattening temperature, flattening pressure, and solder ball size. In other embodiments of the disclosure, the key parameters affecting the process may be a combination of one or more of the foregoing multiple parameters. Please continue to refer to FIG. 4. In procedure S440, the processor 110 may screen parameters by feature engineering to find the foregoing key parameters affecting the manufacturing process.

In the embodiment of the disclosure, the processor 110 may perform a cluster analysis on the process data. That is to say, the processor 110 may find a set of clusters from the process data. The processor 110 may determine a distance between each process data and the set of clusters. Furthermore, the processor 110 may eliminate outlier data from the process data to avoid outliers affecting subsequent parameter selection and model establishment.

In other embodiments of the disclosure, the processor 110 may also directly examine the process data, determine and eliminate obviously erroneous data in the process data. For example, when a value of a first parameter in all process data falls between 0 and 1, and the processor 110 may determine according to ordinary skill in the art that the first parameter does not exceed 1, the processor 110 may delete unreasonable process data where the first parameter is greater than 1 to avoid outliers affecting the subsequent parameter selection and model establishment.

In other embodiments of the disclosure, the processor 110 may also use random forest feature importance or step-wise regression to obtain the key parameters from the process data that have been preprocessed. The parameter screening in procedure S440 of the disclosure is not limited to any specific feature engineering. Any algorithm that may obtain key parameters can serve as a parameter screening process in procedure S440 of the disclosure.

Please continue to refer to FIG. 4. In procedure S450, the processor 110 may establish a machine learning algorithm model. Specifically, the processor 110 may use ridge regression, least absolute shrinkage and selection operator (LASSO), or linear regression and derivative algorithms to establish a linear machine learning algorithm optimization model. Alternatively, the processor 110 may use decision tree, random forest, eXtreme Gradient Boosting (XGBoost), neural network, or gradient boosting regression to establish a non-linear machine learning algorithm optimization model. A manner of establishing the optimization model in procedure S450 of the disclosure is not limited to any specific machine learning algorithm model. Any algorithm that may be used to establish an optimization model may serve as an optimization model establishing process in procedure S450 of the disclosure.

Following the foregoing paragraph, an evaluation index (such as a coefficient of determination R²) of the optimization model obtained by the processor 110 may affect the direction of the procedure. Specifically, if the coefficient of determination R² of the optimization model obtained by the processor 110 is greater than a first evaluation threshold (such as greater than 0.7), the processor 110 may continue to enter procedure S460 of reverse prediction testing on the model. If the processor 110 determines that the coefficient of determination R² is between 0.4 and 0.7 (0.4≤R²≤0.7), the processor 110 may determine that the key parameters selected are insufficient or need adjustment, thus the processor 110 may return to procedure S440 and use a feature engineering different from the foregoing one to obtain key parameters. In this way, it can be understood that different compositions of key parameters may train different optimization models, thereby the processor 110 may obtain an evaluation index of a new optimization model.

Following the foregoing paragraph, if the processor 110 determines that the coefficient of determination R² is less than a second evaluation threshold (such as less than 0.4), the processor 110 may return to procedure S410 to recollect data or increase an amount of data. In addition, the processor 110 may further re-evaluate whether the data collected meet a regular standard of the manufacturing process, such as whether the data collected at least include a consistency of processing machine characteristics or material characteristics. In this way, the evaluation index is enhanced for subsequently establishing the optimization model.

Please continue to refer to FIG. 4. In procedure S460, the processor 110 may perform the reverse prediction testing on the model. Specifically, after each procedure from procedure S410 to procedure S450, the processor 110 further needs to confirm whether the optimization model established is appropriate for subsequent actual application in a production process. In the embodiment of the disclosure, the processor 110 may, for example, input process data not used for establishing the optimization model into the optimization model obtained to determine an effect of the optimization model. In procedure S470, assuming that the effect of the foregoing optimization model meets an expectation, the processor 110 may allow the optimization model to go live for actual usage in a production line. The foregoing index that meets the expectation (a prediction threshold) has, for example, an accuracy greater than or equal to 70%.

Following the foregoing paragraph, if the processor 110 determines that the accuracy is less than 70%, the processor 110 may return the procedure to procedure S410 to recollect data, increase the amount of data, or re-evaluate whether the data collected meet the regular standard of the manufacturing process.

The following Table 1 lists the case results that use at least one procedure from the procedures shown in FIG. 4 according to the disclosure.

TABLE 1

| | Case | | | | Comparative | Comparative |
|---|---|---|---|---|---|---|
| Procedure | Case 1 | Case 2 | Case 3 | Case 4 | example 1 | example 2 |
| S410-S420 | ✓ | ✓ | ✓ | ✓ | ✓ | ✓ |
| S430 | ✓ | ✓ | ✓ | ✓ | ✓ | ✓ |
| S440 | x | x | ✓ | ✓ | ✓ | ✓ |
| S450 | linear | non- | non- | non- | non- | non- |
| | | linear | linear | linear | linear | linear |
| whether S450 | x | x | ✓ | ✓ | x | ✓ |
| uses | | | | | | |
| hyperparameter | | | | | | |
| optimization | | | | | | |
| S460 | x | x | x | ✓ | x | ✓ |

Model Index

| | | | | | | |
|---|---|---|---|---|---|---|
| R² | 0.15- | 0.60- | 0.70- | 0.70- | 0.65- | 0.70- |
| | 0.40 | 0.65 | 0.85 | 0.85 | 0.75 | 0.85 |
| Error MAPE(%) | 8-10 | 6-8 | 5-6 | 5-6 | 5.5-7.0 | 5-6 |
| Reverse | — | — | — | 85- | — | 60- |
| Prediction | | | | 90% | | 85% |
| Accuracy (%) | | | | | | |

In Case 1, the processor 110 collects production data and production specification factors of a solder resist station and a solder ball mounting station. There is a total of approximately 20 parameters. The parameters include known production parameters and measurement parameters of the solder resist process, production parameters and measurement parameters of the solder ball (solder paste) mounting process, and different specification parameters of the production batch (such as types of film materials used, etc.). The number of data is 5,000 data. After simple logical deletion of erroneous data, the processor 110 does not use the feature engineering of procedure S440 to screen parameters. The processor 110 uses the linear machine learning model in procedure S450 without using a hyperparameter optimization. Since the optimization model generated through procedure S450 needs to be evaluated with an evaluation index before entering procedure S460, and a R² in Case 1 is apparently not greater than 0.4, thus procedure S460 may not be entered.

In Case 2, the processor 110 uses the same procedure S410 to procedure S430 as in Case 1. The processor 110 does not use the feature engineering of procedure S440 to screen parameters. The processor 110 uses the non-linear machine learning model in procedure S450 without using the hyperparameter optimization. Since the optimization model generated through procedure S450 needs to be evaluated with an evaluation index before entering procedure S460, and a R² in Case 2 is apparently not greater than 0.7, thus procedure S460 may not be entered.

In Case 3, the processor 110 uses the same procedure S410 to procedure S430 as in Case 1. The processor 110 uses the feature engineering of procedure S440 to screen parameters, and uses the non-linear machine learning model and the hyperparameter optimization in procedure S450. As shown in Table 1, a R² of Case 3 is greater than 0.7. Although in Case 3, there is no model reverse prediction testing to enter procedure S460, at least the evaluation index of the optimization model is greater than a threshold, thus at least the optimization model may serve as the manufacturing process of the disclosure to go live.

In Case 4, the difference from Case 3 is only that the processor 110 further executes the model reverse prediction testing of procedure S460, and the processor 110 further sets upper and lower limits of a parameter range according to the characteristics of the manufacturing process. As shown in Table 1, a model reverse prediction testing accuracy in Case 4 is between 85% and 90%, that is, greater than the expected 70%, thus the optimization model may serve as the manufacturing process of the disclosure to go live.

In Comparative example 1, reference may be made to the procedures of Case 3. The difference between Comparative example 1 and Case 3 is that Comparative example 1 does not use the hyperparameter optimization in procedure S450. As shown in Table 1, a R² of Comparative example 1 is between 0.65 and 0.75. That is to say, the optimization model generated by the processor 110 according to the procedures of Comparative example 1 is between usable and unusable, which also highlights the importance of using the hyperparameter optimization in procedure S450.

In Comparative example 2, reference may be made to the procedures of Case 4. The difference is that the processor 110 does not set the upper and lower limits of a range of a reverse prediction flattening condition in Comparative example 2. As shown in Table 1, a model reverse prediction testing accuracy in Comparative example 2 is between 60% and 85%, that is, between able to go live and unable to go live, which also highlights the importance of setting the upper and lower limits of the range of the reverse prediction flattening condition in procedure S460.

In each embodiment of the disclosure, a definition of a correct reverse prediction testing is: when a flattening condition of the optimization model is used to perform the manufacturing process, a flattening yield is better than a flattening yield where a past flattening condition is used, that is, the prediction is correct.

The disclosure further provides an optimized method for solder ball flattening in a printed circuit board manufacturing process, which may be implemented by the processor 110 of the optimized system 100 for solder ball flattening in the printed circuit board manufacturing process. Each procedure and detailed technical features of the optimized method have been described in the foregoing paragraphs and will not be repeated here.

The optimization model generated by the optimized system and method for solder ball flattening in the printed circuit board manufacturing process of the disclosure may be applied to a flattening procedure in the printed circuit board manufacturing process, and allows the yield of solder ball or solder paste flattening to be enhanced.

In summary, the optimized system and method for solder ball flattening in the printed circuit board manufacturing process provided by the disclosure may generate corresponding flattening condition parameters based on machine characteristics and material characteristics. In subsequent processes, the flattening condition parameters recommended by the optimization model may be used to reduce a problem of poor flattening yield. Through the content of the disclosure, not only can a process of performing trial pressing with a small quantity of sample during trial mass production be decreased, but the flattening yield can also be enhanced to reduce rework.

What is claimed is:

1. An optimized system for solder ball flattening in a printed circuit board manufacturing process, comprising:
a storage, storing a plurality of modules; and
a processor, coupled to the storage, and configured to:
obtain a plurality of data;
perform a preprocessing on the data, wherein the preprocessing comprises performing a classification on the data based on processing machine characteristics and processing material characteristics;
execute a parameter selection module among the modules to obtain a plurality of parameters based on the data;
execute a machine learning module among the modules to establish an optimization model based on the data that have been preprocessed and the parameters; and
execute a prediction module among the modules to perform a reverse prediction testing on the optimization model.

2. The optimized system for solder ball flattening in the printed circuit board manufacturing process according to claim 1, wherein the preprocessing further comprises:
performing a cluster analysis on the data through the processor; and
eliminating a plurality of outlier data from the data that have been cluster analyzed.

3. The optimized system for solder ball flattening in the printed circuit board manufacturing process according to claim 1, wherein the processor is further configured to:
use random forest feature importance or step-wise regression to obtain the parameters based on the data.

4. The optimized system for solder ball flattening in the printed circuit board manufacturing process according to claim 1, wherein the processor is further configured to:
use ridge regression, least absolute shrinkage and selection operator (LASSO), or linear regression to establish a linear optimization model.

5. The optimized system for solder ball flattening in the printed circuit board manufacturing process according to claim 1, wherein the processor is further configured to:
use decision tree, random forest, eXtreme Gradient Boosting (XGBoost), neural network, or gradient boosting regression to establish a non-linear optimization model.

6. The optimized system for solder ball flattening in the printed circuit board manufacturing process according to claim 1, wherein the processor is further configured to:
execute an evaluation module among the modules to perform an evaluation on the optimization model and obtain an evaluation index;
execute the reverse prediction testing in response to the evaluation index being greater than a first evaluation threshold;
execute a second parameter selection module among the modules to obtain a plurality of second parameters in response to the evaluation index not being greater than the first evaluation threshold and the evaluation index not being less than a second evaluation threshold; and
increase an amount of the data in response to the evaluation index being less than the second evaluation threshold.

7. The optimized system for solder ball flattening in the printed circuit board manufacturing process according to claim 6, wherein the processor is further configured to:
execute the machine learning module among the modules to establish a second optimization model based on the data that have been preprocessed and the second parameters in response to obtaining the second parameters.

8. The optimized system for solder ball flattening in the printed circuit board manufacturing process according to claim 6, wherein the processor is further configured to:
perform the preprocessing on the data that have been increased in amount in response to increasing the amount of the data.

9. The optimized system for solder ball flattening in the printed circuit board manufacturing process according to claim 1, wherein the processor is further configured to:
increase an amount of the data in response to an accuracy of the reverse prediction testing being less than a prediction threshold.

10. The optimized system for solder ball flattening in the printed circuit board manufacturing process according to claim 1, wherein the parameters comprise: solder resist open annulus size, flattening temperature, flattening pressure, and solder ball size.

11. An optimized method for solder ball flattening in a printed circuit board manufacturing process, comprising:
obtaining a plurality of data;
performing a preprocessing on the data, wherein the preprocessing comprises performing a classification on the data based on processing machine characteristics and processing material characteristics;
obtaining a plurality of parameters based on the data;
establishing an optimization model based on the data that have been preprocessed and the parameters; and
performing a reverse prediction testing on the optimization model.

12. The optimized method for solder ball flattening in the printed circuit board manufacturing process according to claim 11, wherein the preprocessing further comprises:
performing a cluster analysis on the data; and
eliminating a plurality of outlier data from the data that have been cluster analyzed.

13. The optimized method for solder ball flattening in the printed circuit board manufacturing process according to claim 11, further comprising:
using random forest feature importance or step-wise regression to obtain the parameters based on the data.

14. The optimized method for solder ball flattening in the printed circuit board manufacturing process according to claim 11, further comprising:
using ridge regression, least absolute shrinkage and selection operator (LASSO), or linear regression to establish a linear optimization model.

15. The optimized method for solder ball flattening in the printed circuit board manufacturing process according to claim 11, further comprising:
using decision tree, random forest, eXtreme Gradient Boosting (XGBoost), neural network, or gradient boosting regression to establish a non-linear optimization model.

16. The optimized method for solder ball flattening in the printed circuit board manufacturing process according to claim 11, further comprising:
performing an evaluation on the optimization model and obtaining an evaluation index;
executing the reverse prediction testing in response to the evaluation index being greater than a first evaluation threshold;
obtaining a plurality of second parameters based on the data in response to the evaluation index not being greater than the first evaluation threshold and the evaluation index not being less than a second evaluation threshold; and
increasing an amount of the data in response to the evaluation index being less than the second evaluation threshold.

17. The optimized method for solder ball flattening in the printed circuit board manufacturing process according to claim 16, further comprising:
establishing a second optimization model based on the data that have been preprocessed and the second parameters in response to obtaining the second parameters.

18. The optimized method for solder ball flattening in the printed circuit board manufacturing process according to claim 16, further comprising:
performing the preprocessing on the data that have been increased in amount in response to increasing the amount of the data.

19. The optimized method for solder ball flattening in the printed circuit board manufacturing process according to claim 11, further comprising:
increasing an amount of the data in response to an accuracy of the reverse prediction testing being less than a prediction threshold.

20. The optimized method for solder ball flattening in the printed circuit board manufacturing process according to claim 11, wherein the parameters comprise: solder resist open annulus size, flattening temperature, flattening pressure, and solder ball size.
